(19) United States
(12) Patent Application Publication
(10) Pub. No.: US 2008/0079476 A1
(43) Pub. Date: Apr. 3, 2008

(54) Gate load impedance networks for field effect transistor attenuators and mixers

(76) Inventor: Michael Wendell Vice, El Granada, CA (US)

Correspondence Address: Kathy Manke;Avago Technologies Limited, 4380 Ziegler Road, Fort Collins, CO, 80525, US

(21) Appl. No.: 11/541,475

(22) Filed: Sep. 29, 2006

(51) Int. Cl. H03K 17/687

(52) U.S. Cl. 327/427

(57) ABSTRACT

An electrical circuit having improved linearity across a desired attenuation range includes a shunt circuit having a first field effect transistor (FET) adapted to couple a first signal-carrying electrical node of the electrical circuit to a ground node

### CROSS-REFERENCE TO RELATED APPLICATIONS

The present application is related to U.S. patent application “ATTENUATORS WITH CHANNEL-BIASED FIELD EFFECT TRANSISTORS” to Michael Vice, and having Ser. No. (AVAGO Docket Number: 10060145), filed concurrently. The disclosure of this referenced application is specifically incorporated herein by reference.

### BACKGROUND

The referenced applications are assigned to the present assignee and the disclosures of these applications are specifically incorporated herein by reference.

Designers of RF and microwave systems often rely on resistive field effect transistor (FET) circuits to control the behavior of various signals of interest. For example, designers use both series and shunt FET-based devices in attenuators to variably attenuate high-frequency signals, as well as in mixers to multiply two or more high-frequency signals.

Unfortunately, shunt-configured FETs can create considerable signal distortion due to their inherent non-linearity. Often, the distortion in a shunt-configured FET is worst when the gate bias voltage applied to the FET is approximately half-way between the pinch-off voltage of the FET and the hard-on voltage of the FET. As is known, the pinch-off voltage is the gate voltage that substantially depletes the channel of carriers, causing the FET to behave like an open circuit; and hard-on is the gate voltage that enhances carrier concentration to a substantially maximum level, creating a condition of low resistance in the FET. While this distortion can be reduced by judiciously setting the channel bias, even with the optimal channel bias the distortion can still be excessive.

Therefore, there is a need to improve the linearity of FET-based circuitry.

### SUMMARY

In an illustrative embodiment, an electrical circuit includes a variable resistance shunt circuit having a first field effect transistor (FET) that includes a gate with a conductive channel controlled by the gate, a first channel terminal connected to one end of the conductive channel and a second channel terminal connected to the other end of the conductive channel, wherein the first channel terminal is coupled to a first signal-carrying node and the second channel terminal is coupled to an electrical ground or a virtual ground of the electrical circuit, and a linearizing circuit coupled to both the gate of the first FET and to the virtual ground, wherein the linearizing circuit adapted to alter a driving point impedance of the first FET in a manner as to substantially improve the linearity of the first FET.

In another illustrative embodiment, an electrical circuit includes a variable resistance shunt circuit having a first field effect transistor (FET) that includes a gate with a conductive channel controlled by the gate, a first channel terminal connected to one end of the conductive channel and a second channel terminal connected to the other end of the conductive channel, wherein the first channel terminal is coupled to the first signal-carrying node and the second channel terminal is coupled to an electrical ground or a virtual ground, and a linearizing means coupled to the gate of the first FET for improving the linearity of the first FET.

In yet another illustrative embodiment, a method for modifying an electrical circuit to improve its linearity is disclosed, wherein the electrical circuit includes a variable resistance shunt circuit having a first field effect transistor (FET) that includes a gate with a conductive channel controlled by the gate, a first channel terminal connected to one end of the conductive channel and a second channel terminal connected to the other end of the conductive channel, and wherein the first channel terminal is coupled to the first signal-carrying node and the second channel terminal is coupled to an electrical ground or a virtual ground. The method includes placing a capacitive device between the first FET's gate and the virtual ground to appreciably change the driving point impedance to the first FET.

### DESCRIPTION OF THE DRAWINGS

The example embodiments are best understood from the following detailed description when read with the accompanying drawing figures. Wherever applicable and practical, like reference numerals refer to like elements.

FIG. 1 shows a test configuration for a shunt-configured FET circuit in accordance with a representative embodiment.

FIG. 2 is a graph of a family of distortion curves for the FET circuit of FIG. 1.

FIG. 3 depicts a variation of the graph of distortion curves shown in FIG. 2.

FIG. 4 shows a test configuration for a shunt-configured FET circuit in accordance with another representative embodiment.

FIG. 5 shows a test configuration for a shunt-configured FET circuit in accordance with yet another representative embodiment.

FIG. 6 is a flowchart outlining a process for optimizing the driving point impedance to a shunt-configured FET circuit.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

As discussed above, shunt-configured FETs are often used for high-frequency (>1 GHz) attenuators or mixers. Typically, these FETs are gate-biased using resistors having a large impedance on the order of several thousand ohms. Unfortunately, this large impedance can induce non-linear behavior in a FET as the driving point impedance presented at the gate of the FET is not set for optimal linearity throughout the channel impedance range of the FET. That is, when the appropriate channel (drain-source (V_{DS})) bias is applied to a shunt-configured FET, linearity becomes a sensitive function of the driving point impedance at the gate. As a result, a degree of non-linearity remains in effect because the driving point impedance is not optimized for the channel bias conditions. However, as will become clearer as the present description continues, the present teachings provide a useful remedy thereto.

The embodiments described herein include FETs that may be implemented in a variety of materials. Representative materials include III-V semiconductors such as GaAs, InGaAs, and InGaAsP of selected stoichiometry. Such devices are commonly Metal Semiconductor FETs or MESFETs. However, the embodiments may be realized in other materials such as Si or SiGe. It is emphasized that the noted materials are illustrative and that other materials are contemplated.

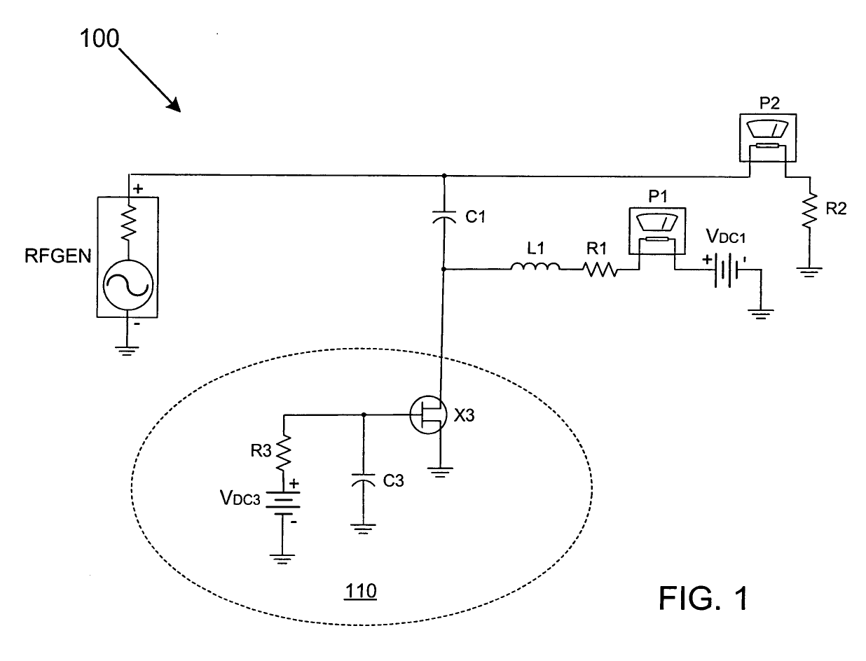

FIG. 1 shows a test configuration 100 for a shunt-configured FET circuit 110 in accordance with a representative embodiment. As shown in FIG. 1, the illustrative test configuration 100 includes a radio-frequency (RF) signal generator RFGEN connected to the shunt-configured FET circuit 110 and a test/measurement arrangement comprising two probes P1 and P2.

The first probe P1 is in series with a channel biasing circuit that includes a voltage source VDC1, a resistor R1 and an inductor L1. The second probe P2 is in series with the generator RFGEN and a termination resistor R2. A DC isolation capacitor C1 is placed between the generator RFGEN and the shunt-configured FET circuit 110.

In operation, the generator RFGEN is adapted to generate a high-frequency signal that will propagate to both the termination resistor R2 via probe P2 and the shunt-configured FET circuit 110 via capacitor C1. The channel biasing circuitry of components VDC1, R1 and L1 can apply an appropriate DC bias to the upper terminal/drain of FET X3 while the isolation capacitor C1 allows the AC components of the generator's RF signal to reach the shunt-configured FET circuit 110 without changing the DC bias. Additionally, voltage source VDC3 can provide a voltage bias at the gate of the FET X3 via resistor R3.

Note that, unlike known shunt-configured FET circuits, the exemplary shunt-configured FET circuit 110 of FIG. 1 includes a compensation capacitor C3 coupled to the gate of FET X3. While the presence of capacitor C3 may serve to limit the switching frequency available to the gate of FET X3 in some application, the benefits of improved linearity can far outweigh this limitation when the capacitance value of capacitor C3 is appropriately selected.

While in the example of FIG. 1 a single capacitor C3 is used to improve linearity, in various embodiments it may be beneficial to add a resistor in series or in parallel with capacitor C3 to alter the impedance in various fashions. For example, by adding a series resistor to capacitor C3, the quality (Q) factor of the driving point impedance to FET X3 may be lowered, or the overall stability or performance of the shunt-configured FET circuit 110 may be otherwise subtly changed.

Although capacitor C3 is shown coupled to the electrical ground of the test circuit 100, it is emphasized that any “virtual ground” node might also be used. As used herein, the term “virtual ground” may refer to electrical ground or any electrical node (e.g., a power supply node) that has an appreciably low AC impedance with respect to the electrical ground at frequencies of interest. Further, for shunt-configured FET circuits arranged in a balanced circuit (as opposed to the single-ended circuit example of FIG. 1), a node in the balanced circuit having a substantially zero voltage with respect to electrical ground, and about which voltage the balanced circuit operates with substantial symmetry might also serve as a virtual ground node.

Accordingly, for the various descriptions presented herein, while the terms “ground” or “electrical ground” may be used for convenience of explanation, it will be recognized by those of ordinary skill in the art that a virtual ground node may be substituted for those reference nodes commonly referred to as ground, signal ground or electrical ground with identical or nearly identical results expected to be seen. Moreover, it is emphasized that several separate electrical nodes, including electrical ground and power supply nodes, can be considered to be a single virtual ground as is recognized by those of ordinary skill in the art.

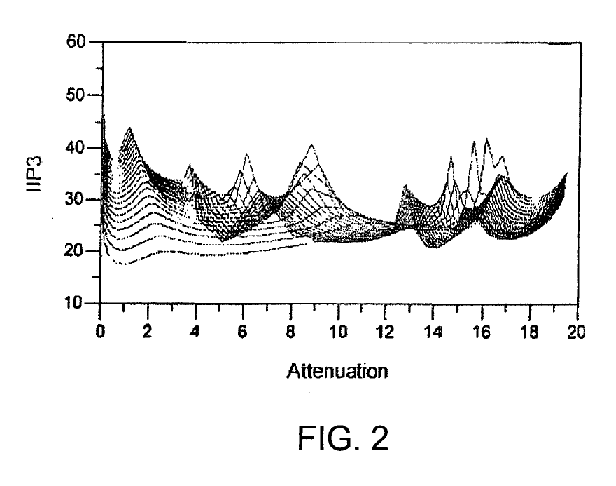

FIG. 2 is a graph of a family of third-order intercept distortion curves for the shunt-configured FET circuit 110 of FIG. 1 using a variety of capacitance values for capacitor C3. The various performance curves were derived via simulation for approximately 20 separate capacitance values ranging from approximately 0.0 pF to approximately 2.0 pF in 0.1 pF increments over an attenuation range of approximately 0.0 to approximately 20.0 db.

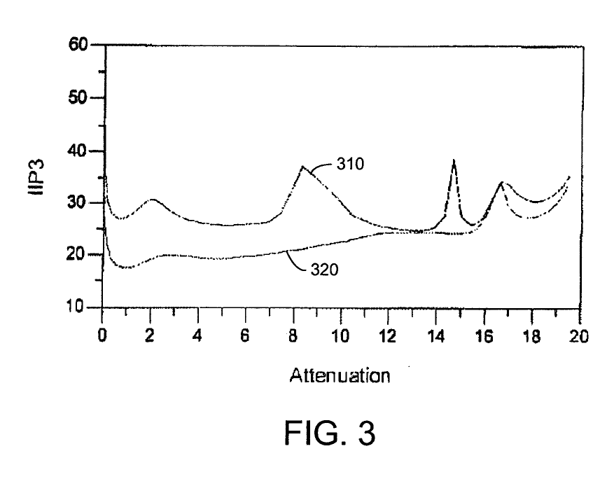

Continuing to FIG. 3, a variation of the graph of FIG. 2 is presented where only two of the approximately twenty performance curves are presented including: (1) a third-order intercept curve 320 for a FET having no compensation capacitor; and (2) a third-order intercept curve 310 for a FET showing optimal performance, which for curve 310 represents a FET having an added gate capacitance of 0.5 pF.

As is inferred by FIG. 3, the addition of an optimal capacitance value to the gate of a FET can favorably change the driving point impedance to the FET. The practical results include that the third-order intercept point of the FET is improved over the entire 0-20 db attenuation range with notably good improvement (7-10 db) in the 0-10 db attenuation range.

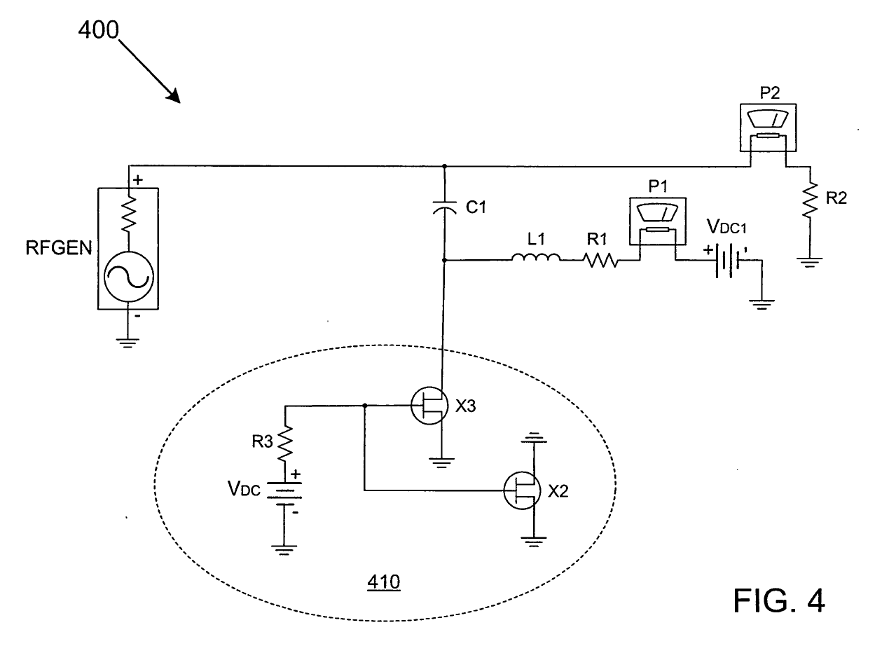

FIG. 4 shows a test configuration for a shunt-configured FET circuit in accordance with another representative embodiment. As shown in FIG. 4, the test circuit 400 of the present embodiment is substantially the same as the test circuit 100 of FIG. 1, with the exception that the shunt-configured FET circuit 410 uses second FET X2 in place of capacitor C3. The second FET X2 is arranged such that its gate is directly connected to the gate of FET X3 while its source and drain are connected to ground. While there are obvious differences between a simple capacitor and a FET transistor, the second FET X2 nonetheless can provide an effective capacitance to the gate of FET X3.

In various embodiments it may be useful to leave one of either the source or drain terminals of FET X2 open, or otherwise couple the source and/or drain of FET X2 to ground via some other impedance. For example, in order to lower the Q-factor of the driving point impedance to FET X3, a resistor may be placed in series with FET X2 between the source/drain and ground, or alternatively a resistor may be placed between the gate of FET X2 and the gate of FET X3.

A benefit of using the second FET X2, as opposed to a capacitor, is that the second FET X2 can be placed in proximity to the first FET on a common semiconductor substrate. Accordingly, FETs X3 and X2 can share all process variations. As a result, any process variation that would change the gate admittance of FET X3 would also cause a change in the gate admittance of FET X2.

In the embodiment shown in FIG. 4, experimentation has shown that the optimal size of FET X2 is about one-half the size of the shunt-configured FET X3. In this disclosure, the term “size” is meant to refer to the area that a FET occupies on a substrate. For example, if the shunt-configured FET X3 occupies an area of 4.0 μm by 4.0 μm on a given substrate, then an optimally-sized compensation FET X2 might occupy an area of 4.0 μm by 2.0 μm, and be located adjacent to FET X3. Alternatively, the term “size” may refer to total gate periphery, i.e. gate width, in processes that construct the FET as a lateral device.

It is noted that the disclosed optimal size ratios for the embodiment shown in FIG. 4 are representative. It is emphasized that a change to the configuration of FET X2, such as leaving its drain open or adding a series resistor, may lead to a different optimal size ratio between FET X2 and FET x3.

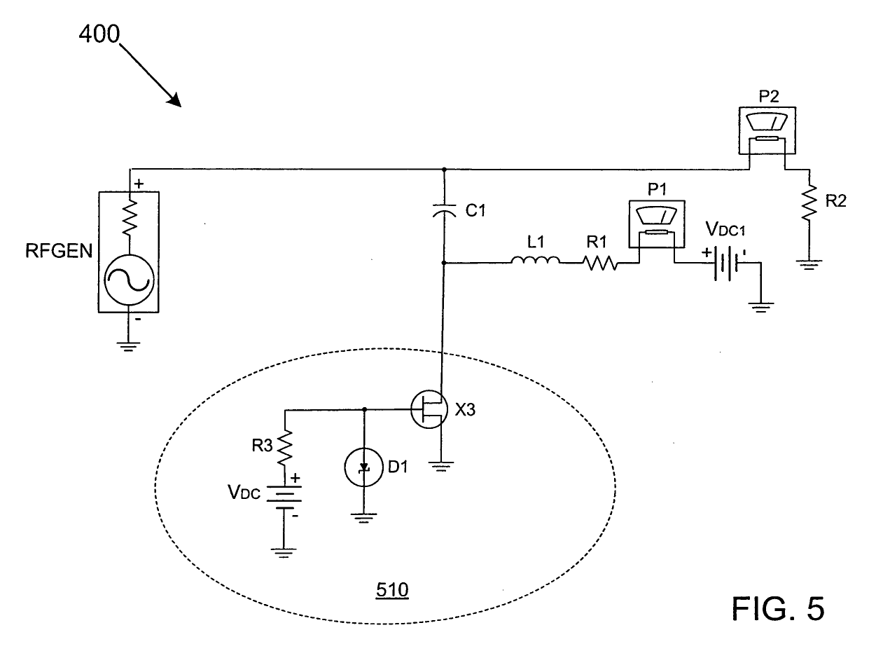

FIG. 5 shows a test configuration for a shunt-configured FET circuit in accordance with yet another representative embodiment. As shown in FIG. 5, the present test circuit 500 is identical to the test circuit 100 of FIG. 1 with the exception that the shunt-configured FET circuit 510 of FIG. 5 uses a Schottky diode D1 in lieu of a capacitor. As with the second FET X2 of FIG. 4, the diode D1 can be placed in proximity to the first FET on a common semiconductor substrate. Thus, any process variation that would change the gate admittance of FET X3 would also affect diode D1.

Note that, in the particular embodiments described above, FETs X2 and FET X3 can be either n-channel or p-channel junction field effect transistor (JFET) devices made from a wide range of materials ranging from silicon to category III-V gallium arsenide materials. The diode D1 of FIG. 5 may be made from similar materials. Further, while the exemplary FETs X2 and FET X3 are junction field effect transistor (JFET) devices, in various other embodiments MOSFET devices may be substituted.

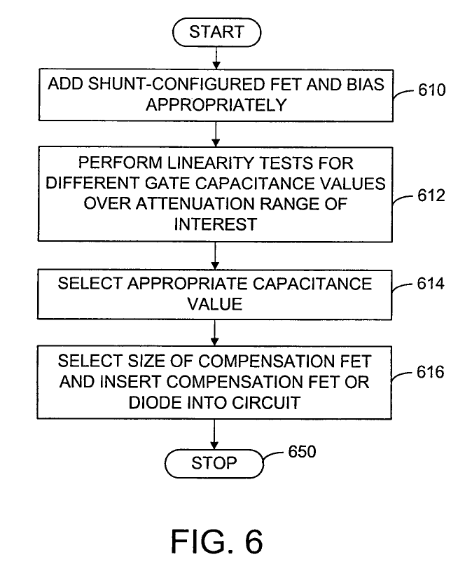

FIG. 6 is a flowchart outlining a process for optimizing gate impedance of a shunt-configured FET circuit. The process starts in step 610 where a FET is added to a circuit design in a shunt configuration with its gate and channel biased appropriately. Next, in step 612, a series of linearity tests can be performed using various capacitive values coupled between the gate of the shunt-configured FET and a ground node. Then, in step 614, the capacitance value showing the best performance in step 612 can be selected. Control continues to step 616.

In step 616, a compensation FET or diode can be inserted into the circuit design in lieu of a capacitor. In various embodiments, the size of a compensating FET or diode can be selected based on the optimal capacitance value found in step 614. However, in other embodiments the size of the FET or diode may be determined based on some general design rule, e.g., using a compensation FET being one-half the size of the shunt-configured FET of step 610. Control then continues to step 650 where the process stops.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. An electrical circuit, comprising:
a variable resistance shunt circuit having a first field effect transistor (FET) that includes: a gate with a conductive channel controlled by the gate; a first channel terminal connected to one end of the conductive channel; and a second channel terminal connected to the other end of the conductive channel, wherein the first channel terminal is coupled to a first signal-carrying node and the second channel terminal is coupled to an electrical ground or a virtual ground of the electrical circuit; and
a linearizing circuit coupled to both the gate of the first FET and to the virtual ground, wherein the linearizing circuit is adapted to alter a driving point impedance of the first FET in a manner as to substantially improve the linearity of the first FET.

2. The electrical circuit of claim 1, wherein the linearizing circuit includes a capacitive device that provides a predominately capacitive impedance to the gate of the first FET.

3. The electrical circuit of claim 2, further comprising a gate biasing circuit coupled to the gate of the first FET and adapted to control a bias point of the first FET.

4. The electrical circuit of claim 2, wherein the capacitive impedance of the capacitive device is selected as a function of the physical size of the first FET.

5. The electrical circuit of claim 2, wherein the capacitive device includes at least one of a second FET and a Schottkey diode.

6. The electrical circuit of claim 5, wherein the capacitive device further includes a resistor configured in a manner as to lower a quality factor of the capacitive device

7. The electrical circuit of claim 5, wherein the capacitive device includes at least a second FET.

8. The electrical circuit of claim 7, wherein the first and second FETs are junction field effect transistors (JFETs).

9. The electrical circuit of claim 8, wherein the first FET and the capacitive device are category III-V devices.

10. The electrical circuit of claim 5, wherein the FET and the capacitive device are disposed in close proximity to one another on a common semiconductor substrate.

11. The electrical circuit of claim 2, wherein the capacitive device includes a second FET having a size approximately one-half the size of the first FET, and wherein the gate of the second FET is coupled to the gate of the first FET and at least one channel terminal of the second FET is coupled to the virtual ground.

12. The electrical circuit of claim 2, wherein the capacitive device includes a capacitor coupled to the virtual ground.

13. The electrical circuit of claim 2, wherein the virtual ground includes the electrical ground of the electrical circuit.

14. The electrical circuit of claim 1, wherein the virtual ground includes a balanced signal line.

15. The electrical circuit of claim 1, wherein the electrical circuit is an attenuation circuit.

16. An electrical circuit, comprising:
a variable resistance shunt circuit having: a first field effect transistor (FET) that includes a gate with a conductive channel controlled by the gate; a first channel terminal connected to one end of the conductive channel; and a second channel terminal connected to the other end of the conductive channel, and wherein the first channel terminal is coupled to the first signal-carrying node and the second channel terminal is coupled to an electrical ground or a virtual ground; and
a linearizing means coupled to the gate of the first FET for improving the linearity of the first FET.

17. The electrical circuit of claim 16, wherein linearizing means includes a second FET having a physical size approximately one-half the size of the first FET and configured such that the gate of the second FET is coupled to the gate of the first FET.

18. A method for modifying an electrical circuit to improve its linearity, wherein the electrical circuit includes a variable resistance shunt circuit having a first field effect transistor (FET) that includes a gate with a conductive channel controlled by the gate, a first channel terminal connected to one end of the conductive channel and a second channel terminal connected to the other end of the conductive channel, and wherein the first channel terminal is coupled to the first signal-carrying node and the second channel terminal is coupled to an electrical ground or a virtual ground, the method comprising:
providing a capacitive device between the gate of the first FET and the virtual ground to appreciably change the driving point impedance to the first FET.

19. The method of claim 18, wherein the capacitive device includes at least one of a second FET, a diode and a capacitor.

20. The method of claim 19, wherein the capacitive device includes a second FET having a size approximately one-half the size of the first FET, and wherein the gate of the second FET is coupled to the gate of the first FET and both channel terminals of the second FET are coupled to the virtual ground.
